(19) United States
(12) Patent Application Publication
(10) Pub. No.: US 2010/0290202 A1
(43) Pub. Date: Nov. 18, 2010

(54) Semiconductor package, lead frame, and wiring board with the same

(75) Inventors: Hideki Sasaki, Kanagawa (JP); Kenji Nishikawa, Kanagawa (JP); Muneharu Morioka, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Renesas Electronics Corporation, Kawasaki (JP)

(21) Appl. No.: 12/662,811

(22) Filed: May 4, 2010

(30) Foreign Application Priority Data
May 13, 2009 (JP) 2009-116765

(51) Int. Cl. H05K 7/06; H01L 23/495; H01L 23/28

(52) U.S. Cl. 361/767; 257/666; 257/787; 257/E23.031; 257/E23.116

(57) ABSTRACT

A semiconductor package comprises a conduction member, a semiconductor chip mounted on and electrically connected to the conduction member, and a sealing body configured to seal the conduction member and the semiconductor chip. The conduction member comprises a power supply section configured to supply a power voltage to said semiconductor chip, a ground section configured to supply a ground voltage to the semiconductor chip, and a signal section connected to a signal terminal of the semiconductor chip. The power supply section, the ground section, and the signal section are arranged so as not to overlap each other. At least a part of said ground section is exposed on an under surface of the sealing body. The power supply section comprises an exposed region of which bottom surface is exposed on the under surface, and a plurality of power hanging-pin region configured to extend to a side of the sealing body from the exposed region.

### INCORPORATION BY REFERENCE

This patent application claims a priority on convention based on Japanese Patent Application No. 2009-20398. The disclosure thereof is incorporated herein by reference.

### BACKGROUND OF THE INVENTION

1. Field of the Invention

The present invention relates to a semiconductor package, a lead frame, a wiring board with the same.

2. Description of Related Art

A semiconductor chip is sealed by a sealing body to be used as a semiconductor package. FIG. 1 is a schematic cross section diagram showing one example of the semiconductor package described in document 1 (Japanese patent publication JP-A-Heisei 11-251494). This semiconductor package 101 includes an island 102, a semiconductor chip 104, a lead 103, a bonding wire 105, and a sealing body 106. The semiconductor chip 104 is mounted on the island 102 and is sealed by the sealing body 106. The island 102 is exposed on an under surface of the sealing body 106. The lead 103 protrudes outside from inside of the sealing body 106 at a side of the sealing body 106. The lead 103 includes a power supply terminal and a signal terminal. The semiconductor chip 104 is electrically connected to the island 102 and the lead 103 via the bonding wires 105. The island 102 functions as the ground and supplies a ground reference voltage to the semiconductor chip 104.

When the island 102 is exposed on the under surface of the sealing body 106 like the example shown in FIG. 1, heat radiation of the semiconductor chip can be improved. When a ground region is provided on a wiring substrate on which the semiconductor package 101 is mounted, such that the ground region faces to the island, the ground region can be connected to the island in a wide area, and heat of the semiconductor chip can be easily transferred to the ground region via the island 102. Further, since the island 102 contacts the ground region in a wide area, power impedance formed between the ground of the semiconductor chip and the ground of the wiring board can be reduced, and the ground reference voltage can be stable. However, in the lead 103, a power supply terminal is provided to be close to the signal terminal. For this reason, noises are easily generated in a signal by inductance of the power supply. Further, the distance between the power supply terminal and the semiconductor chip becomes longer than that between the ground and the semiconductor chip. For this reason, the impedance of the power supply becomes larger. In order to solve these problems, the power supply terminals need to be increased in number, and a size of the semiconductor package is enlarged.

On the other hand, in document 2 (Japanese patent publication JP-A-Heisei 9-219488), a technology for reducing a parasitic parameter, such as impedance of a power supply and thermal resistance, to perform a stable operation is described. In document 2, it is described that one end of a first lead connected to a first terminal provided in a semiconductor element, one end of a second lead connected to a power supply terminal, and one end of a third lead connected to a ground terminal are bonded to each other with a non-conducting adhesive so as to form layers. Further, it is described that the second lead and the third lead are exposed on an under surface of a semiconductor package.

### SUMMARY

According to the description of document 2, since inductance of the power supply can be reduced and the leads can be separated from each other, noises generated by the inductance of a power supply wire can be suppressed during a switching operation, and supply of the noises to a signal terminal can be prevented.

However, according to a semiconductor device described in document 2, a plurality of lead frames are needed, and a manufacturing process becomes complex to increase a cost.

A semiconductor package according to the present invention includes, a conduction member, a semiconductor chip mounted on and electrically connected to the conduction member, and a sealing body configured to seal the conduction member and the semiconductor chip. The conduction member includes, a power supply section configured to supply a power voltage to the semiconductor chip, a ground section configured to supply a ground voltage to the semiconductor chip, and a signal section connected to a signal terminal of the semiconductor chip. The power supply section, the ground section, and the signal section are arranged so as not to overlap each other. At least a part of the ground section is exposed on an under surface of the sealing body. The power supply section includes, an exposed region exposed on the under surface, and a plurality of power hanging-pin region configured to extend toward a side of the sealing body from the exposed region.

According to the present invention, impedance of the power supply can be suppressed and heat radiation can be increased, since the ground section supplies a ground voltage to the semiconductor chip and the power supply section and the ground section are exposed on the under surface of the sealing body. Furthermore, the power supply section is fixed with the plurality of power supply hanging-pin regions, and the power supply section and the ground section are arranged so as not to overlap. For this reason, the ground section and the power supply section are prevented from contacting. Furthermore, the power supply section, the ground section, and the signal section can be obtained from one conduction plate. Accordingly, in the semiconductor package, impedance of the power supply can be suppressed and the heat radiation can be improved, without complicating a manufacturing process.

The lead frame according to the present invention includes, a frame section having frame shape, and a conduction member extending to an inner side from the frame part. The conduction member includes, a power supply section configured to supply a power voltage to a semiconductor chip mounted on the conduction member, a ground section configured to supply a ground voltage to the semiconductor chip, and a signal section connected to a signal terminal of the semiconductor chip. The power supply section includes, an exposed region, and a plurality of power hanging-pin regions configured to couple the frame section and the exposed region to support the exposed region. The conduction member is arranged so as not to overlap.

The wiring board according to the present invention is a wiring board on which above mentioned semiconductor package is mounted. The wiring board includes, a power supply terminal provided on a principal surface, a ground terminal provided on the principal surface, and a decoupling capacitor provided on a bottom surface. The power supply terminal is connected to the power supply section exposing on the under surface. The ground terminal is connected to the ground section exposing on the under surface. One end of the decoupling capacitor is electrically connected to the power supply terminal via a through hole. Another end of the decoupling capacitor is electrically connected to the ground terminal via a through hole.

The vehicle mounted microcomputer according to the present invention includes, above mentioned semiconductor package. The semiconductor package has a function for controlling a device provided in a vehicle.

The disk drive device according to the present invention includes, the above mentioned semiconductor package, and an optical disk reading/writing mechanism configured to read and write on an optical disk device. The semiconductor chip controls an operation of the optical disk reading/writing mechanism.

The method for manufacturing a semiconductor package according to the present invention includes, preparing a lead frame comprising a frame section and a conducting section extending to inside of the frame section from the frame section, mounting a semiconductor chip on the conducting section, electrically connecting the semiconductor chip and the conducting section by a bonding wire, sealing the conducting section and the semiconductor chip, and cutting the conducting section to separate from the frame section after the sealing. The preparing comprises, punching or etching a conductive plate to have the frame section and the conducting section. The conducting section comprises, a power supply section configured to supply power voltage to the semiconductor chip, a ground section configured to supply ground voltage to the semiconductor chip, and a signal section connected to a signal terminal of the semiconductor chip. The power supply section comprises, an exposed region, and a plurality of power supply hanging-pin regions configured to extend to the frame section from the exposed region. The sealing comprises, exposing a part of the exposed region and the ground section on an under surface of a sealing body.

According to the present invention, a semiconductor package, a lead frame, a disk drive device, a vehicle-mounted microcomputer, and a method for manufacturing a semiconductor package are provided, which enable to improve heat radiation, reduce power supply impedance, and reduce noises without complicating a manufacture process.

### BRIEF DESCRIPTION OF DRAWINGS

The above and other objects, advantages and features of the present invention will be more apparent from the following description of certain preferred embodiments taken in conjunction with the accompanying drawings, in which:

FIG. 1 is a schematic cross section view showing one example of a semiconductor package;

FIG. 2A is a perspective plan view showing a semiconductor package according to a first embodiment;

FIG. 2B is a perspective plan view showing the semiconductor package according to the first embodiment;

FIG. 2C is a perspective plan view showing a variation example of the semiconductor package according to the first embodiment;

FIG. 3 is a section view along a plane A-A′ of FIG. 2B;

FIG. 4 is a section view along a plane B-B′ of FIG. 2B;

FIG. 5 is a plan view showing an under surface of the semiconductor package according to the first embodiment;

FIG. 6 is a schematic section view showing a state in which the semiconductor package according to the first embodiment is mounted on a wiring board;

FIG. 7 is a plan view showing a principal surface of the wiring board;

FIG. 8 is a plan view showing a bottom surface of the wiring board;

FIG. 9 is a schematic cross section view showing a semiconductor device according to a comparative example;

FIG. 10A is a schematic cross section view showing a semiconductor package of a variation example;

FIG. 10B is a schematic cross section view showing a semiconductor package of another variation example;

FIG. 11 is a flow chart showing a method for manufacturing a semiconductor package;

FIG. 12 is a flow chart showing a method for manufacturing a lead frame;

FIG. 13 is a plan view showing a lead frame;

FIG. 14 is a plan view showing a mounting area;

FIG. 15 is a schematic cross section view showing a semiconductor package according to a second embodiment;

FIG. 16 is a flow chart showing a method for manufacturing a lead frame;

FIG. 17 is a perspective plan view showing-a semiconductor package according to a third embodiment;

FIG. 18 is a section view along a plane C-C′ of FIG. 17;

FIG. 19A is a perspective plan view showing a semiconductor package according to a fourth embodiment;

FIG. 19B is a perspective plan view showing a semiconductor package according to a variation of the fourth embodiment;

FIG. 20A is a perspective plan view showing a semiconductor package according to a fifth embodiment;

FIG. 20B is a perspective plan view showing a semiconductor package according to a modification of the fifth embodiment;

FIG. 21 is a cross section view schematically showing a vehicle-mounted microcomputer; and

FIG. 22 is a view schematically showing a disk drive device.

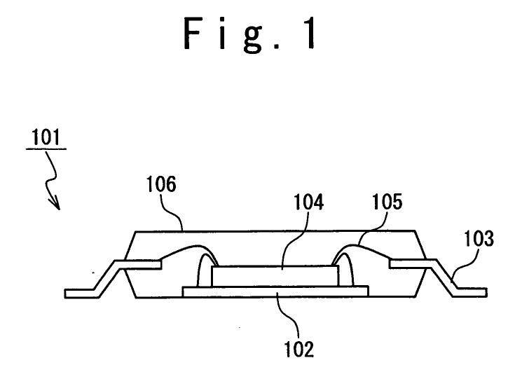

### DESCRIPTION OF THE PREFERRED EMBODIMENTS

### First Embodiment

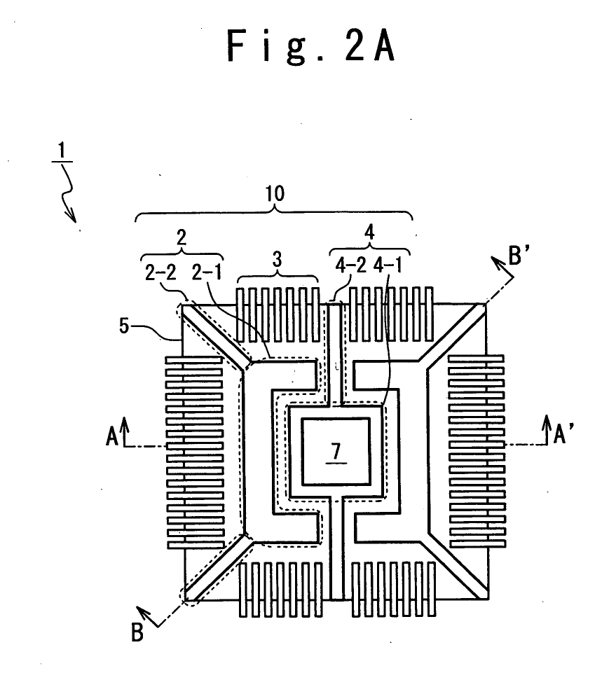

Hereinafter, a first embodiment of the present invention will be described with reference to the drawings. FIG. 2A and FIG. 2B are perspective plan views each showing a semiconductor package 1 according to the present embodiment. In FIG. 2A, bonding wires 6 are omitted so as to easily show the semiconductor package 1. In FIG. 2B, the bonding wires 6 are illustrated.

As shown in FIG. 2A, the semiconductor package 1 has a sealing body 5, a conducting member 10, and a semiconductor chip 7. The semiconductor chip 7 is sealed with the sealing body 5. The sealing body 5 is ordinarily a rectangular solid.

The conducting member 10 has a plate shape and is made of copper or the like. The conducting member 10 has a signal section 3, a ground section 4, and a power supply section 2. These sections are arranged so as not to overlap each other.

The ground section 4 supplies a reference voltage of 0 V (ground voltage) to the semiconductor chip 7. The ground section 4 has an island part 4-1 and a ground hanging-pin region 4-2.

The island part 4-1 is a region on which the semiconductor chip 7 is mounted. The island part 4-1 is provided on a central portion of an under surface of the sealing body 5. The semiconductor chip 7 is bonded to a central portion of the island part 4-1 with an adhesive (not shown) such as a silver paste, and the adhesive has high thermal conductivity. In the island part 4-1, a ground connection region is provided, on which the semiconductor chip 7 is not arranged. The ground connection region is connected to the bonding wires 6. The ground connection region is connected to ground terminals of the semiconductor chip 7 through the bonding wires 6. The ground hanging-pin region 4-2 may be connected to the ground terminals of the semiconductor chip 7 through the bonding wires 6.

The ground hanging-pin region 4-2 is provided for supporting the island part 4-1 with a frame section, which will be described later. The ground hanging-pin region 4-2 is arranged on two positions. Each of the ground hanging-pin regions 4-2 extends toward a central portion of a side of the sealing body 5.

The power supply section 2 is provided for supplying a power voltage to the semiconductor chip 7. The power supply section 2 is divided into a plurality of (two) power supply regions, and two power supply regions are provided on both sides of the ground section 4. Each of the power supply regions has an exposed region 2-1 and a power supply hanging-pin region 2-2. When the semiconductor chip 7 needs two power supply systems, two different power supply voltages are supplied to the semiconductor chip 7 through two power supply regions. For example, a voltage of 3.3 V is applied to one power supply region, and a voltage of 2.5 V is applied to the other power supply region. However, when the semiconductor chip 7 needs only one power supply system, same power supply voltages are supplied to the semiconductor chip 7 via two power supply regions.

The exposed region 2-1 has a bottom surface exposed on the under surface of the sealing body 5. A principal surface of the exposed region 2-1 is connected to the semiconductor chip 7 via the bonding wires 6. The exposed region 2-1 is provided to surround the island part 4-1 except for the ground hanging-pin region 4-2. In the example shown in FIG. 2A, two exposed regions 2-1 are provided on both sides of the ground hanging-pin region 4-2.

The power supply hanging-pin region 2-2 is provided for supporting the exposed region 2-1. A plurality of (two in this embodiment) power supply hanging-pin regions 2-2 are coupled to one exposed region 2-1. Each of the power supply hanging-pin regions 2-2 extends toward a corner of the sealing body 5 from the exposed region 2-1. The power supply hanging-pin region 2-2 may be connected to a power supply terminal of the semiconductor chip 7 via the bonding wires 6. Moreover, the number of the power supply hanging-pin region 2-2 is not limited to two but may be three or more. As mentioned above, it is described that the semiconductor chip 7 needs two power supply systems in the present embodiment. However, the semiconductor chip 7 can have three or more power supply systems when three or more exposed regions 2-1 are provided

The signal section 3 is provided for inputting/outputting a signal between the semiconductor chip 7 and an external device. The signal section 3 has many signal leads. Each of the signal leads protrudes outside from an inside of the sealing body 5 at the side of the sealing body 5. Each of the signal leads is connected to the semiconductor chip 7 via the bonding wire 6 at an inside end. In other words, the semiconductor package 1 according to the present embodiment is a so-called QFP (Quad Flat Package)-type semiconductor package.

FIG. 2C is a perspective plan view showing a semiconductor package according to a variation of the present embodiment. In the variation, a power supply lead region 2-3 is added in the power supply section 2. Moreover, a ground lead region 4-3 is added in the ground section 4. The power supply lead region 2-3 is connected to the power supply hanging-pin region 2-2 and protrudes on a side of the sealing body 5. Further, the ground lead region 4-3 is coupled to the ground hanging-pin region 4-2 and protrudes on the side of the sealing body 5. According to this construction, the power voltage and the ground reference voltage can be applied to the semiconductor chip 7 by the power supply lead region 2-3 and the ground lead region 4-3, and impedance generated between the power supply and the ground can be further reduced. Both of the power supply lead region 2-3 and the ground lead region 4-3 may be provided, and either of them may be provided.

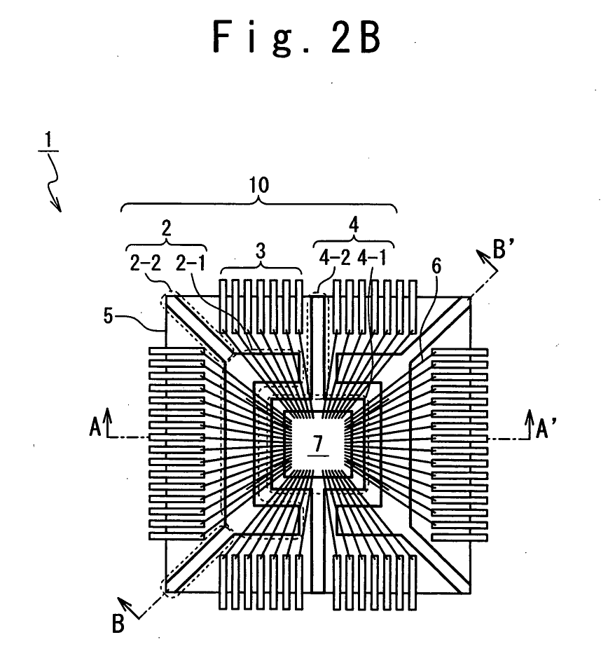

FIG. 3 is a perspective section view showing a plane A-A′ of FIG. 2B. As shown in FIG. 3, the exposed region 2-1 and the ground connection region (island part) 4-1 are exposed on the under surface of the sealing body 5. Further, the signal section 3 is bent at outside of the sealing body 5 so that one end is positioned at a level equal to the under surface of the sealing body 5.

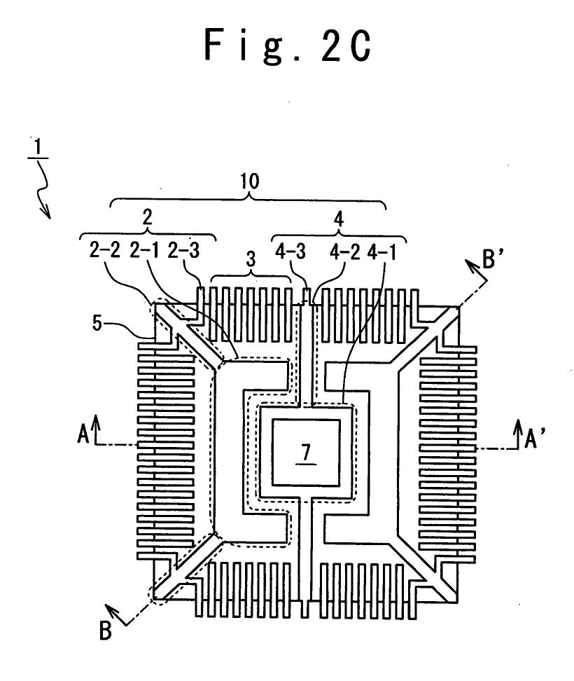

FIG. 4 is a section view showing a plane B-B′ of FIG. 2B and is a section view showing the power supply hanging-pin region 2-2. As shown in FIG. 4, the power supply section 2 is bent such that the power supply hanging-pin region 2-2 passes through the inside of the sealing body 5. Although not shown in the drawing, the ground section 4 is also bent in the same way, and the ground hanging-pin region 4-2 is also positioned inside of the sealing body 5.

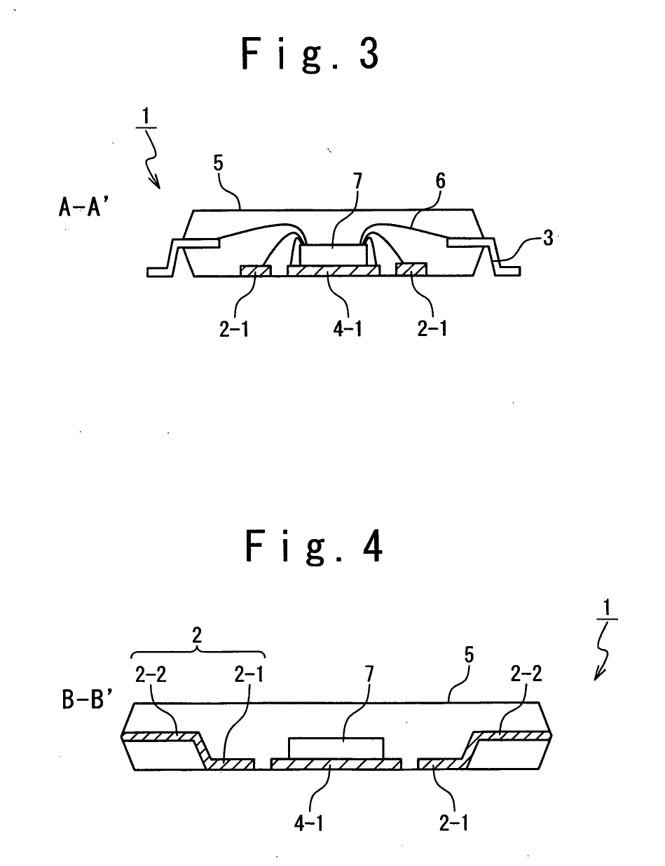

FIG. 5 is a plan view showing the under surface of the semiconductor package 1. As shown in FIG. 5, only the exposed region 2-1 and the island part 4-1 are exposed on the under surface.

As described above, each of the power supply section 2 and the ground section 4 is exposed on the under surface of the sealing body 5. As a result, heat radiation can be increased.

Further, since a portion of the power supply section 2 is arranged on the under surface, the boding wires 6 can be shorter in length, as compared with a case where the power supply section 2 protrudes outside from a side of the sealing body 5. As a result, impedance can be reduced, which is generated between the exposed region 2-1 and the semiconductor chip 7. Similarly, since the island part 4-1 is arranged on the under surface of the sealing body 5, the boding wires 6 connecting the island part 4-1 and the semiconductor chip 7 can be shorter in length. As a result, impedance can be reduced, which is generated between the island part 4-1 and the semiconductor chip 7.

When the power supply section 2 is arranged on the under surface, power supply terminals can be deceased in number which protrudes from the side of the sealing body 5. In other words, since only the signal leads protrude from the side of the sealing body 5, the semiconductor package can be reduced in size.

Furthermore, in the present embodiment, the power supply section 2 (exposed region 2-1) is arranged on the under surface of the sealing body 5 so as to surround the ground section 4 (island part 4-1). In other words, the power supply section 2 and the ground section 4 are neighbored each other at a wide region on the under surface. As a result, many decoupling capacitors can be easily arranged on a wiring board, on the under surface of the semiconductor package 1, or inside of the semiconductor package 1. When many decoupling capacitors are arranged near the semiconductor package 1, electromagnetic interference (hereinafter referred to as EMI) can be decreased, which is caused by a power supply current of high frequency. This will be described below in detail.

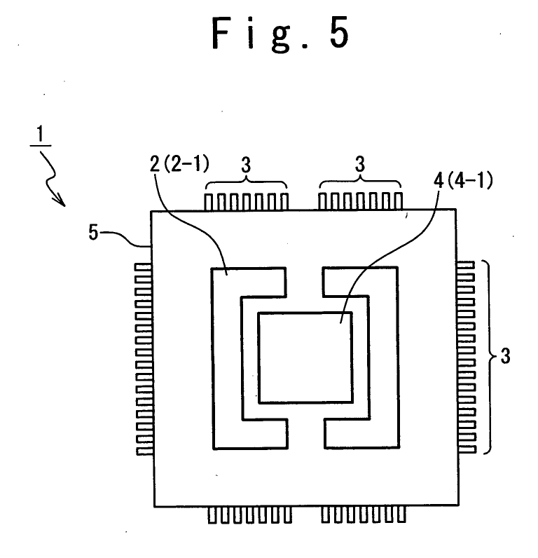

FIG. 6 is a schematic section view showing a semiconductor device according to the present embodiment. The semiconductor device has the abovementioned semiconductor package 1, and a wiring board 8 on which the semiconductor package 1 is mounted. On the bottom surface of the wiring board 8, decoupling capacitors 11 are provided. A lead (signal section) 3 of the semiconductor package 1 and an electrode of the decoupling capacitor are connected to terminals provided on a principal surface of the wiring board 8, via solder. The wiring board 8 has through holes 9. One end of the decoupling capacitor 11 is connected to the power supply section 2 via the through hole 9, and another end is connected to the ground section 4 via the through hole 9. Here, the decoupling capacitor 11 is exemplified by a chip capacitor.

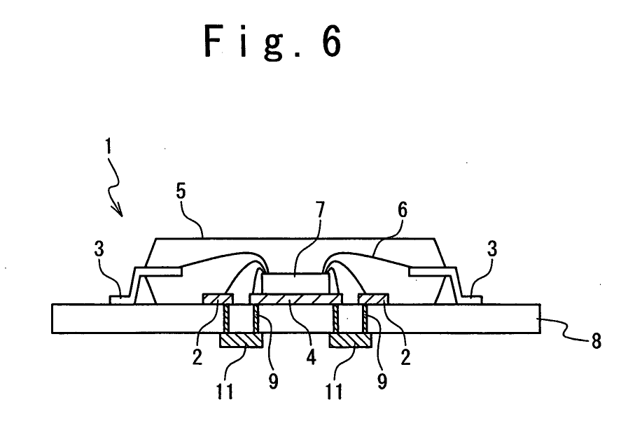

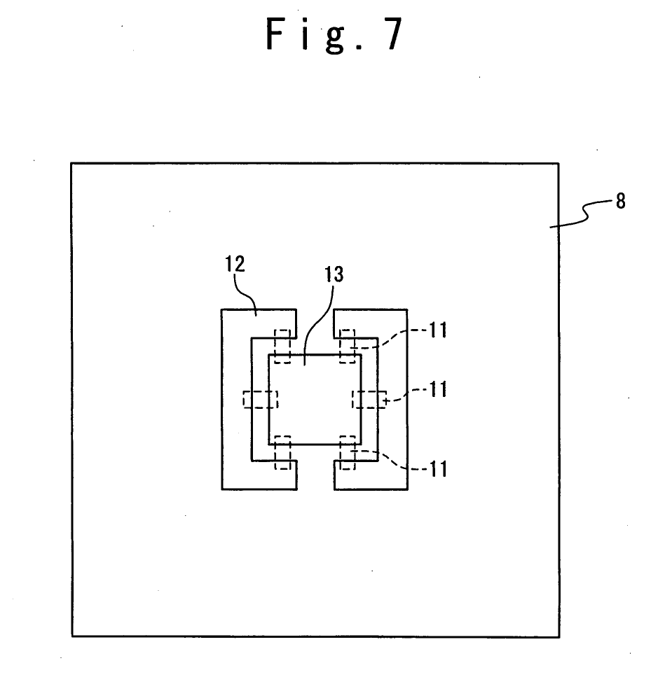

FIG. 7 is a plan view (in which a signal terminal for a lead is omitted in the drawing) showing a principal surface of the wiring board 8. FIG. 8 is a plan view showing a bottom surface of the wiring board 8. As shown in FIG. 7, on the principal surface, power supply terminals 12, a ground terminal 13, and lead (signal section) terminals (not shown) are provided. The power supply terminal 12 is provided in a shape corresponding to the exposed region 2-1. The ground terminal 13 is provided in a shape corresponding to the island part 4-1. On the other hand, as shown in FIG. 8, on the bottom surface, many (six in FIG. 8) decoupling capacitors 11 are arranged. In each of the decoupling capacitors 11, one end is connected to the power supply terminal 12, and the other end is connected to the ground terminal 13. Here, since the power supply terminal 12 and the ground terminal 13 are neighbored in a wide region, many decoupling capacitors 11 can be arranged on the bottom surface.

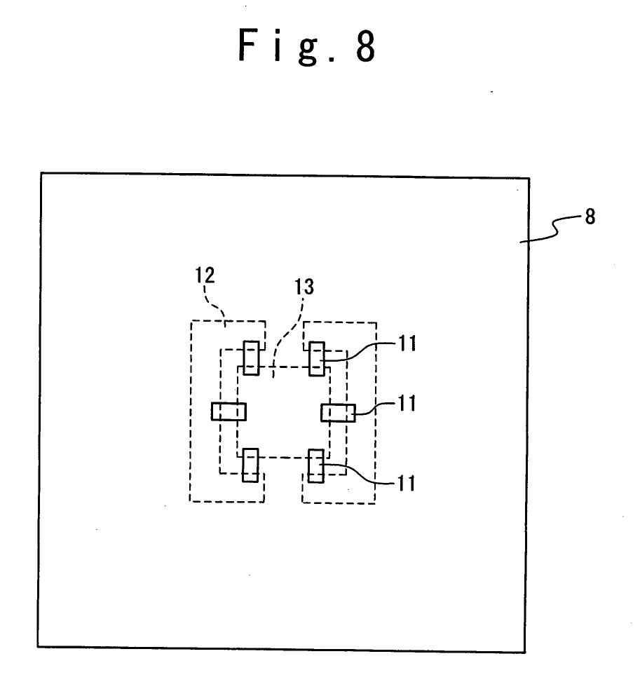

Next, an effect of the present invention will be described in comparison with a comparative example. FIG. 9 is a schematic cross section view showing a semiconductor device according to the comparative example. An operating frequency of a semiconductor chip has been higher in recent years. For example, in a semiconductor device for controlling a vehicle-mounted microcomputer or a disk drive device, the operating frequency has been increased from several tens MHz to several hundreds MHz or more. Thus, it is important to decrease not only a ground impedance but also total impedance including a power supply impedance and a decoupling capacitors impedance. Impedance formed between the power supply and the ground will be described with reference to FIG. 9. A power supply terminal 202 on the semiconductor chip 7 is connected to the power supply section 2 (a portion of leads of the signal section is used as the power supply section) via the bonding wire 6. The power supply section 2 is connected to one end of the decoupling capacitor 11 via a wiring 14 provided on the principal surface of the wiring board 8. On the other hand, the other end of the decoupling capacitor 11 is connected to a wiring 14 provided on the bottom surface of the wiring board 8 via the through hole 9. The wiring 14 provided on the bottom surface is connected to the ground section 4 via the through hole 9 provided under the ground section 4. The ground section 4 is connected to a ground terminal 204 provided on the semiconductor chip 7, via a bonding wire or a through electrode (not shown) formed in the semiconductor chip 7. In this manner, in the semiconductor device shown in FIG. 9, even though the ground section 4 is exposed, considering connection of the ground section 4 and the decoupling capacitor 11, a loop formed between the power supply terminal 202 and the ground terminal 204 is long. As a result, there is a problem that impedance cannot be sufficiently reduced between the power supply and the ground. Further, there is a problem that the loop acts as a loop antenna to cause unnecessary electromagnetic interference (EMI). In the loop antenna, the electromagnetic interference increases, when a loop area formed by the loop is large and a frequency of a current flowing through the loop is high. For this reason, the loop area needs to be smaller and a loop length needs to be shorter, in order to decrease the electromagnetic interference.

On the other hand, according to the semiconductor device according to the present embodiment, many decoupling capacitors 11 can be arranged under the semiconductor package 1. Accordingly, the length of the loop, which is formed by the power supply terminal 12, the decoupling capacitor 11 and ground terminal 13, can be shorter, and the electromagnetic interference can be decreased.

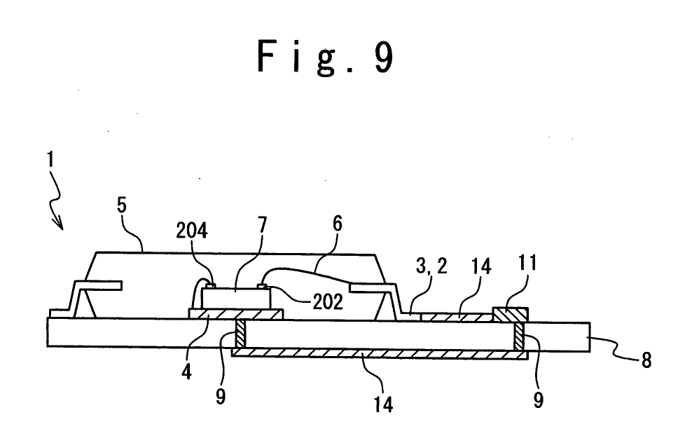

The decoupling capacitors 11 can be also arranged in the semiconductor package 1. FIG. 10A is a schematic cross section view showing a semiconductor package 1 according to a variation of the present embodiment. In this variation, the decoupling capacitors 11 are sealed by the sealing body 5. Both ends of the decoupling capacitor 11 are respectively connected to the power supply section 2 and the ground section 4, via a protruding bump made of solder or gold, or a silver paste. In this manner, even in a case where the decoupling capacitors 11 are arranged in the semiconductor package 1, the power supply section 2 and the ground section 4 are neighbored each other in a wide region, and many decoupling capacitors 11 can be easily arranged.

Further, the decoupling capacitors 11 can be also arranged on the under surface of the sealing body 5. FIG. 10B is a schematic cross section view showing a semiconductor package 1 according to another variation of the present embodiment. In the other variation, the decoupling capacitors 11 are arranged on the under surface of the sealing body 5. The decoupling capacitor 11 is formed in a sufficiently small thickness, and the power supply section 2 and the ground section 4 can be connected to respective terminals of the wiring board at the under surface. The decoupling capacitor 11 has an electrode formed only on its top surface. Both ends on the top surface of the decoupling capacitor 11 are respectively connected to the power supply section 2 and the ground section 4, via protruding bumps made of solder or gold. In the embodiments described above, a case is explained where the decoupling capacitors 11 are arranged in the semiconductor package 1 (FIG. 10A) or under the semiconductor package 1 (FIG. 10B). However, the decoupling capacitors 11 may be arranged in the wiring board 8. For example, in FIG. 6, the decoupling capacitors 11 can be arranged in the wiring board 8. As a method for arranging the decoupling capacitors 11 in the wiring board 8, a method for arranging passive components (capacitors) in the wiring board 8 or a method for forming capacitors in the wiring board 8 by forming a dielectric film is considerable.

In order to arrange the exposed region 2-1 so as to neighbor the ground section 4 in the wide region as described above, the exposed region 2-1 needs to be large to some extent. However, when the exposed region 2-1 is large, there is also a possibility that the exposed region 2-1 becomes unstable when sealing the exposed region 2-1 with resin. For this reason, in the present embodiment, a plurality of power supply hanging-pin regions 2-2 are provided. With the plurality of power supply hanging-pin regions 2-2, the exposed region 2-1 can be stably supported at the time of manufacture (at the time of sealing the exposed region 2-1 with resin). Hereinafter, this point will be described in detail by describing a method for manufacturing the semiconductor package 1 according to the present embodiment.

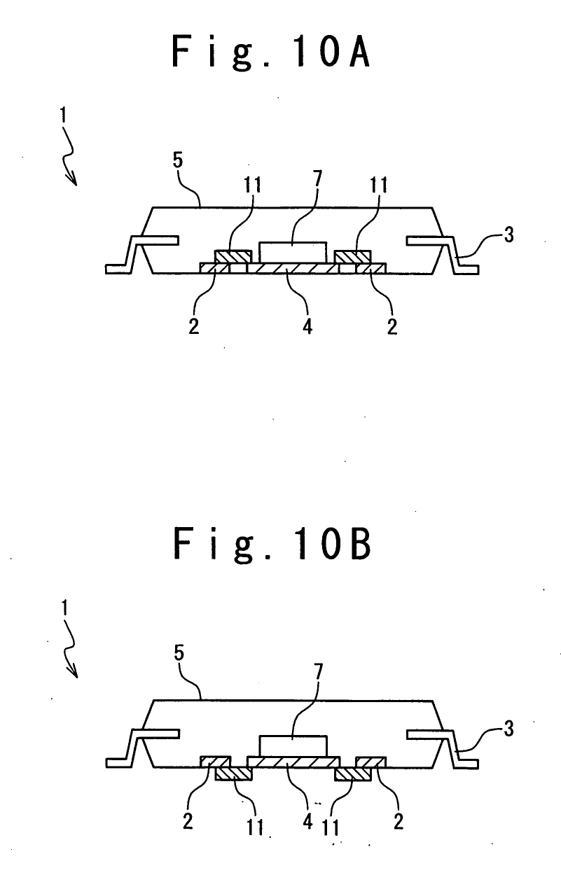

FIG. 11 is a flow chart showing a method for manufacturing the semiconductor package 1 according to the present embodiment.

### Step S1; Preparation of Lead Frame

First, a lead frame is prepared. The lead frame is a member that is finally cut to be a conducting member 10.

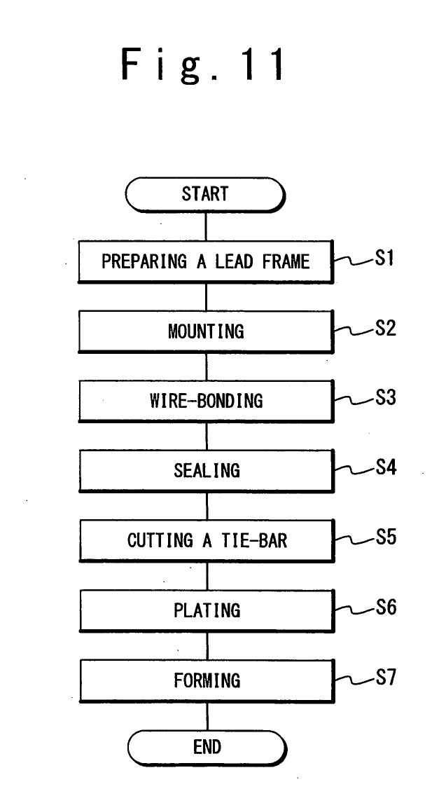

FIG. 12 is a flow chart showing a process for manufacturing the lead frame. First, a shape (pattern) of the lead frame is designed (Step S9). Subsequently, a conducting plate, which is flat, is prepared, and an etching mask is formed on the conducting plate to have a shape corresponding to the designed shape (Step S10). Then, the conducting plate is etched by use of the etching mask, and the lead frame is obtained (Step S11). At this time, since the conducting member 10 are arranged so as not to overlap, the lead frame can be obtained from one conducting plate. As a material of the conducting plate, a copper alloy, and an iron-nickel based alloy are exemplified.

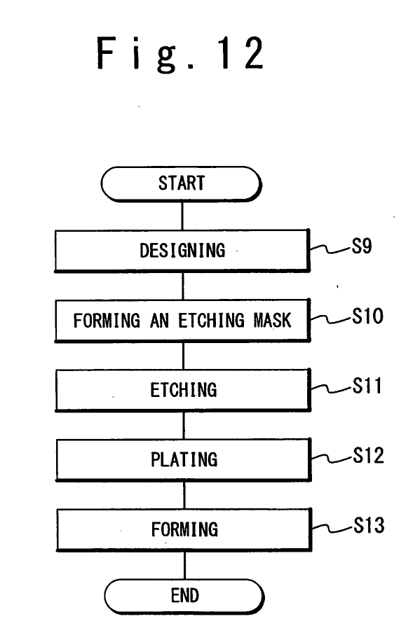

FIG. 13 is a plan view showing a lead frame 15 after patterning. The lead frame 15 after the patterning is flat. A plurality of mounting areas 16 are set on the one lead frame 15.

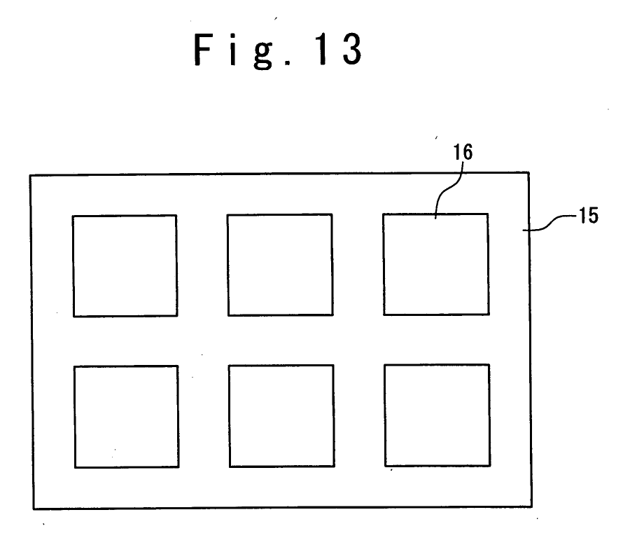

FIG. 14 is a plan view showing each mounting area 16. In FIG. 14, shaded portions show aperture portions. The mounting area 16 has a frame section 17, the signal section 3, the power supply section 2 (the exposed regions 2-1 and the power supply hanging-pin regions 2-2), and the ground section 4 (the island part 4-1 and the ground hanging-pin region 4-2). Further, in FIG. 14, a region that is finally sealed with the sealing body 5 is shown as a sealing area 19.

In the mounting area 16, one exposed region 2-1 is linked to the frame section 17 via a plurality of (two) power supply hanging-pin regions 2-2. Since the exposed region 2-1 is connected to the frame section 17 via the plurality of power supply hanging-pin regions 2-2, the exposed region 2-1 is stably supported. Even if the exposed region 2-1 is large, since the exposed region 2-1 is supported stably, a short circuit caused by a contact of the power supply and the ground is prevented.

The island part 4-1 is linked to the frame section 17 via a plurality of (two) ground hanging-pin regions 4-2.

The signal section 3 includes many signal leads, and each of the signal leads extends from the frame section 17 to a central portion of the mounting area 16. The signal leads adjacent to each other are connected by a tie bar 18 at an outside of the sealing area 19.

The lead frame 15 obtained in Step S11 is plated at an inner portion (inner lead portion) of the signal section 3, in order to improve a bonding ability (Step S12). For example, the inner portion of the signal section 3 is plated with silver.

Then, the lead frame 15 is formed (Step S13). That is, the exposed region 2-1 and the island part 4-1 are pressed down.

According to the processes of Steps S9 to S13 described above, the lead frame 15 is manufactured. Hereinafter, a method for manufacturing a semiconductor package will be described below with reference to FIG. 11 again.

### Step S2; Mounting

The semiconductor chip 7 is mounted on the each mounting area 16 of the lead frame 15 prepared by Step 1 (S9 to S13). The semiconductor chip 7 is bonded onto the island part 4-1 with a silver paste.

### Step S3; Wire Bonding

Subsequently, the semiconductor chip 7 is connected to the lead frame 15 by the bonding wires. Specifically, the exposed region 2-1 is connected to the power supply terminal of the semiconductor chip 7. Moreover, the island part 4-1 is connected to the ground terminal of semiconductor chip 7. Further, each signal lead of the signal section 3 is connected to each signal terminal of the semiconductor chip 7 at an inner lead portion.

### Step 4; Sealing

Subsequently, the sealing area 19 is sealed with a sealing resin. Specifically, the lead flame 15 is placed on a lower die for resin sealing, an upper die is arranged on the lower die, a sealing resin is poured into a cavity to seal the lead frame 15, and the poured sealing resin is cured. At this time, the lead frame 15 is sealed so that the exposed region 2-1 and the island part 4-1 are exposed on the under surface of the sealing body 5.

### Step S5; Tie-Bar Cutting

Subsequently, the tie bar 18 is cut. As a result, the plurality of signal leads are separated from each other in the signal section 3.

### Step 6; Plating

Subsequently, the lead frame 15 is plated at a portion not covered with the sealing body 5. In other words, the exposed region 2-1 and the island part 4-1, which are exposed on the under surface of the sealing body 5, and the signal section 3 are plated. As the plating, tin-bismuth plating and tin plating can be exemplified.

### Step 7; Forming

Subsequently, an unnecessary portion of the lead frame 15 is cut, and the signal section 3 is bent at outside of the sealing body 5. As a result, an end of the signal section 3 is aligned to the under surface of the sealing body 5. Further, a plurality of semiconductor devices 1 are obtained by one lead frame 15.

In the manufacturing method shown in FIG. 11, the plating process may be omitted by using a plating process described below. In the plating step (Step 12) of a method for manufacturing a lead frame shown in FIG. 12, the lead frame 15 is not plated with silver but is plated with nickel/palladium/gold or the like to form three layers. By using the lead frame 15 plated to form three layers, Step 6 shown in FIG. 11 can be omitted, and the number of processes can be reduced.

As described above, according to the present embodiment, not only the ground section 4 but also the power supply section 2 is exposed on the under surface of the sealing body 5, the heat radiation can be further improved.

Moreover, since the ground section 4, the power supply section 3 and the signal section 3 are arranged so as not to overlap each other, the conducting member 10 can be manufactured from one plate. As a result, a manufacture process can be simple, compared to a case where a plurality of leads are overlapped as described in document 2. In the present embodiment, a case is explained where the conducting plate is patterned by etching in Steps S10 and S11. However, the conducting plate may be patterned by punching in place of etching. Even when the conducting plate is patterned by punching, the conducting member 10 can be manufactured from one conducting plate.

Further, since the power supply section 2 is arranged on the under surface of the sealing body 5, the distance between the semiconductor chip 7 and the power supply section 2 can be decreased. Thus, the length of the bonding wire for connecting the semiconductor chip 7 and the power supply section 2 can be decreased to reduce power supply impedance.

Further, both of the power supply section 2 and the ground section 4 are arranged on the under surface of the sealing body 5, the area of a loop formed between the power supply section 2 and the ground section 4 can be shorter. Accordingly, the electromagnetic interference by the loop can be suppressed.

Still further, since the plurality of power supply hanging-pin regions 2-2 are provided, the exposed region 2-1 can be supported stably at the time of manufacture. As a result, the exposed region 2-1 can be arranged in a large area. Thus, the exposed region 2-1 and the ground section 4-1 can be neighbored in a wide region. As a result, many decoupling capacitors 11 can be easily arranged, near the semiconductor package 1, on the wiring board, on the under surface of the semiconductor package 1, and inside of the semiconductor package 1. As a result, between the semiconductor chip and the decoupling capacitor, the area size of the loop can be reduced to decrease impedance between the power supply and the ground. Furthermore, since the area size of the loop can be decreased, unnecessary electromagnetic interference (EMI) can be suppressed.

The present embodiment has the following advantage in the manufacture as compared with document 2. That is, in a semiconductor device described in document 2, a plurality of leads are cut to be separated. Then, the leads are overlaid, and overlapped parts are bonded with a non-conducting adhesive. This process needs a plurality of lead frames. On the other hand, in the present embodiment, one conducting plate is formed into a lead frame by pressing or etching, and there is an advantage that only one lead frame is fundamentally needed.

Further, in the semiconductor device described in document 2, since a plurality of leads need to be overlaid and bonded to each other, the leads are easily shifted in position during the manufacturing process. Especially, when the second lead connected to the power supply and the third lead connected to the ground are shifted in position to contact with each other, a short circuit occurs between the power supply and the ground. On the other hand, according to the present embodiment, there is not a process for overlaying and bonding the leads, and the problem described above is not occurs.

### Second Embodiment

Subsequently, a second embodiment will be described. In the first embodiment, the QFP-type semiconductor package was described. On the other hand, a semiconductor package 1 according to the present embodiment is a QFN (Quad Flat Non-leaded Package)-type semiconductor package. The detailed descriptions of the same points as in the first embodiment will be omitted.

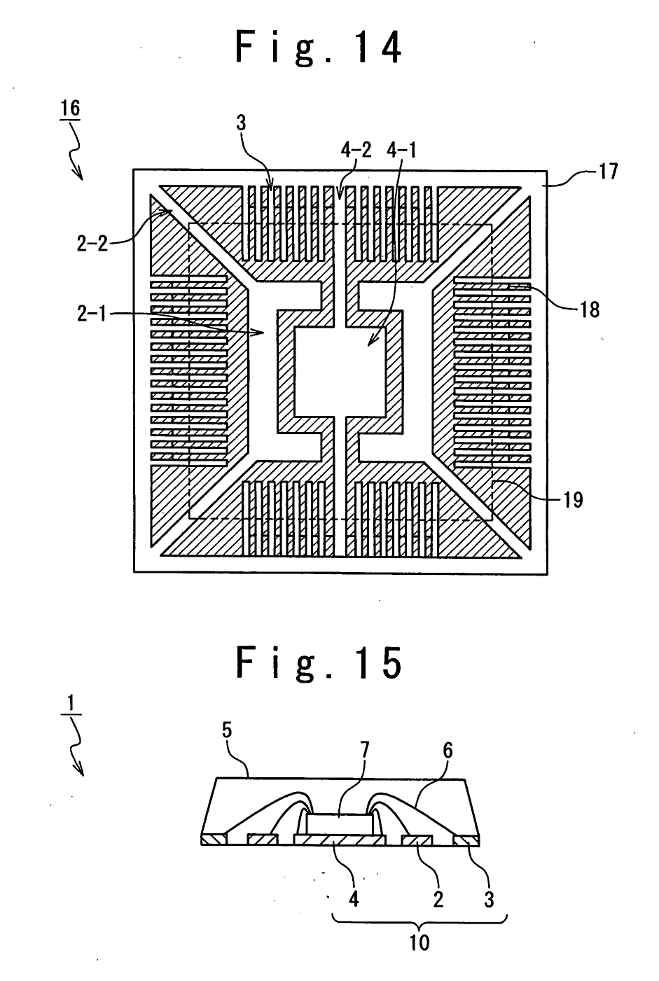

FIG. 15 is a schematic cross section view showing the semiconductor package 1 according to the present embodiment.

As shown in FIG. 15, in the semiconductor package 1, a conducting member 10 is arranged on the same plane as an under surface of a sealing body 5. In other words, not only the ground section 4 and the power supply section 2 but also the signal section 3 is exposed on the under surface of the sealing body 5. Moreover, although not shown in FIG. 15, the power supply hanging-pin region 2-2 and the ground hanging-pin region 4-2 are thinner than the other portions. For this reason, the power supply hanging-pin region 2-2 and the ground hanging-pin region 4-2 are not exposed on the under surface of the sealing body 5 but are embedded in the sealing body 5.

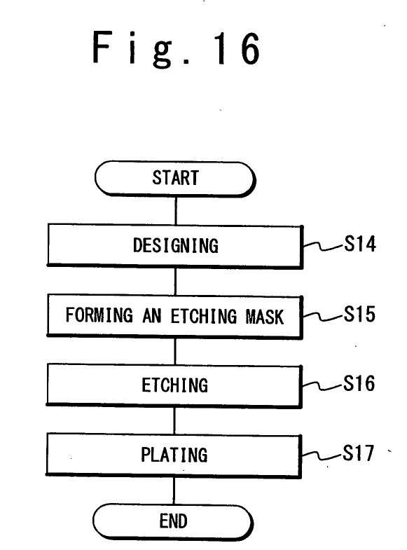

FIG. 16 is a flow chart showing a method for manufacturing a lead frame according to the present embodiment. A shape of the lead frame is designed in the same way as in the first embodiment (Step S14). Then, an etching mask is formed (Step S15). Then, etching is performed (Step S16). The present embodiment is different from the first embodiment in a point that the power supply hanging-pin region 2-2 and the ground hanging-pin region 4-2 are formed to be thinner by half etching in Steps S15 and S16. Then, plating is performed (Step S17). Further, the present embodiment is different from the first embodiment in a point that the island part 4-1 and the exposed region 2-1 are not needed to be pressed down as shown in FIG. 4. Thus, a forming process (Step S13 in FIG. 12) can be omitted.

The present embodiment is the same in the other points as the first embodiment. As described above, even if the QFN-type semiconductor package is used like the present embodiment, the same effects as in the embodiment described above can be obtained. Further, when the QFN-type semiconductor package is used, the signal lead does not need to be protruded from the side of the sealing body 5, the size of the semiconductor package can be reduced.

### Third Embodiment

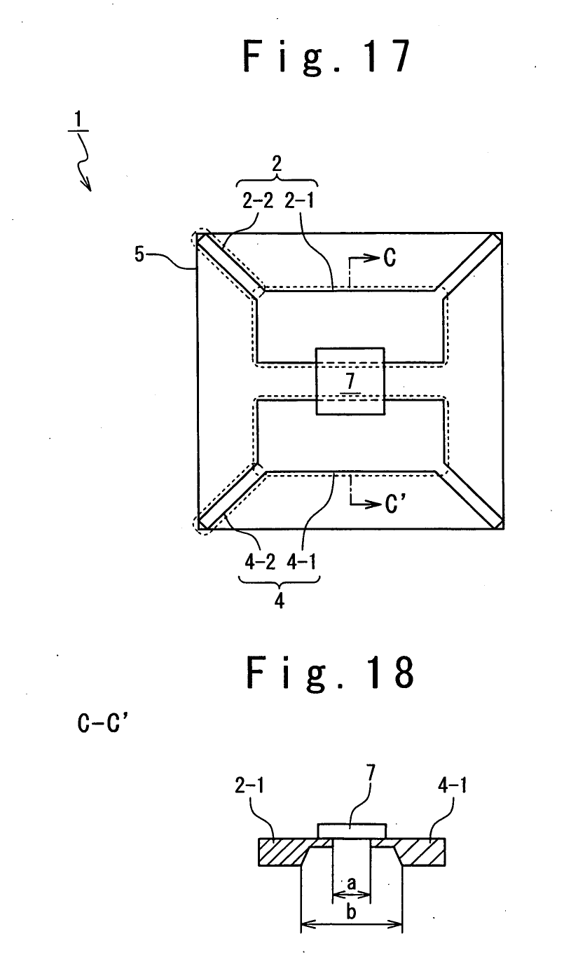

Subsequently, a third embodiment of the present invention will be described. FIG. 17 is a perspective plan view showing a semiconductor package 1 according to the present embodiment. The present embodiment is different from the above-mentioned embodiments, in an arrangement of a power supply section 2 and a ground section 4. The other points can be same as the embodiments described above. Thus, the detailed description will be omitted.

As shown in FIG. 17, a semiconductor chip 7 is arranged on both of the exposed region 2-1 and the island part 4-1. Further, the semiconductor chip 7 is bonded onto the exposed region 2-1 and the island part 4-1 with an insulating adhesive tape (not shown). When a liquid adhesive such as a silver paste is used, there is a possibility that a short circuit occurs between the exposed region 2-1 and the island part 4-1. Accordingly, the insulating adhesive tape is used.

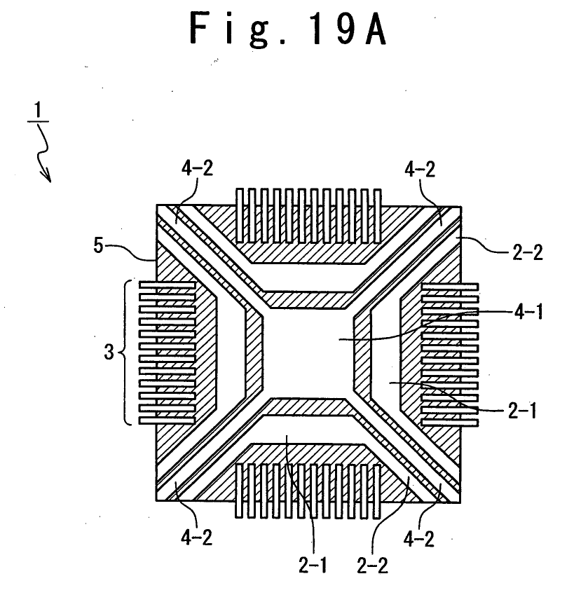

FIG. 18 is a section view showing a plane C-C′ of FIG. 17. As shown in FIG. 18, each of the exposed region 2-1 and the island part 4-1 has a step formed in end portion. The step can be formed by half-etching at the time of manufacturing.

With the step, a gap (gap a) formed between the exposed region 2-1 and the island part 4-1 on a principal surface is narrower than that on a bottom surface (gap b). Since the gap a is narrower, semiconductor chip 7 can be mounted stably. On the other hand, since the gap b is wider, a space between a power supply terminal and a ground terminal can be increased on the wiring board. As a result, when the semiconductor package is mounted on the wiring board, a short circuit between the power supply and the ground can be prevented, and the mounting is easily carried out.

### Fourth Embodiment

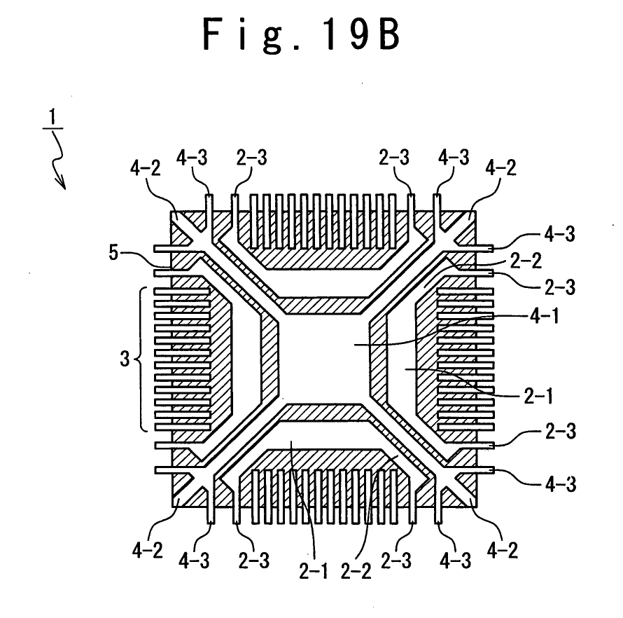

Subsequently, a fourth embodiment of the present invention will be described. FIG. 19A is a perspective plan view showing a semiconductor package 1 according to the present embodiment. The present embodiment is different from the embodiments described above in the arrangement of the power supply section 2 and the ground section 4. The present embodiment can be made similar to the embodiments described above in the other points. Thus, the detailed description of the present embodiment will be omitted.

As shown in FIG. 19A, in the ground section 4, the ground hanging-pin region 4-2 extends toward a corner of a side of a sealing body 5 from the island part 4-1. Further, in the power supply section 2, the exposed region 2-1 is arranged so as to surround the island part 4-1 except for the ground hanging-pin region 4-2. Each power supply region 2-2 extends toward a corner of a side of the sealing body 5 from the exposed region 2-1.

According to the present embodiment, both of the power supply hanging-pin region 2-2 and the ground hanging-pin region 4-2 extend toward the corner. For this reason, as compared with the first embodiment, many signal leads can be arranged in a central portion of the side of the sealing body 5. Moreover, four different power supply potentials can be supplied to the power supply terminals of a semiconductor chip 7 from the exposed regions 2-1.

FIG. 19B is a perspective plan view showing a semiconductor package according to a variation of the present embodiment. As shown in FIG. 19B, in this variation, the ground section 4 additionally includes a ground lead part 4-3. Moreover, the power supply section 2 additionally includes a power supply lead part 2-3. One end of the ground lead part 4-3 is connected to the ground hanging-pin region 4-2. The ground lead part 4-3 extends so as to protrude outside at a side of the sealing body 5 in a manner similar to a signal lead. One end of the power supply lead part 2-3 is linked to the power supply hanging-pin region 2-2. The power supply lead part 2-3 extends outside so as to protrude at the side of the sealing body 5 in a manner similar to the signal lead. With this construction, a power supply voltage and a reference voltage of 0 V can be applied also from the power supply lead part 2-3 and the ground lead part 4-3. Thus, impedance between the power supply and the ground can be further reduced.

### Fifth Embodiment

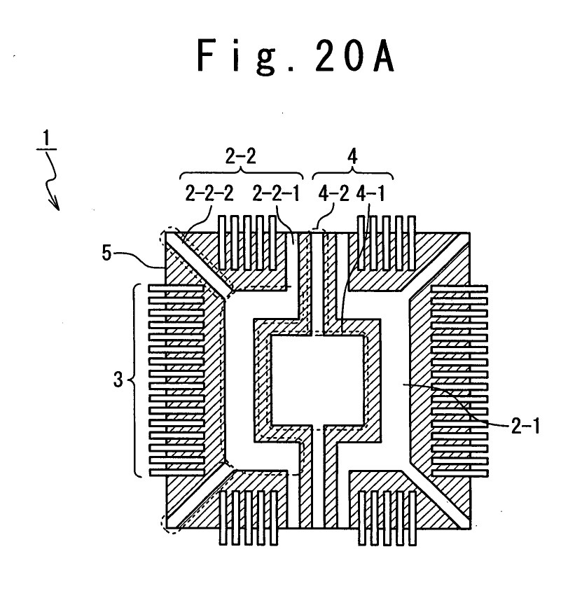

Subsequently, a fifth embodiment of the present invention will be described. FIG. 20A is a perspective plan view showing a semiconductor package 1 according to the present embodiment. The present embodiment is different from the embodiments described above, in the arrangement of the power supply section 2 and the ground section 4. The present embodiment can be made similar in the other points to the embodiments described above. Thus, the detailed description of the present embodiment will be omitted.

As shown in FIG. 20A, the island part 4-1 is arranged in a central portion. The ground hanging-pin region 4-2 extends to a central portion of a side of a sealing body 5 from the island part 4-1.

The exposed region 2-1 of the power supply section 2 is arranged so as to surround the island part 4-1 except for the ground hanging-pin region 4-2. The power supply section 2 includes a central power supply hanging-pin region 2-2-1 and a corner power supply hanging-pin region 2-2-2. The central power supply hanging-pin region 2-2-1 extends toward a central portion of a side of the sealing body 5 from the exposed region 2-1. The corner power supply hanging-pin region 2-2-2 extends toward a corner of a side of the sealing body 5 from the exposed region 2-1.

According to the present embodiment, since the power supply section 2 has the central power supply hanging-pin region 2-2-1 and the corner power supply hanging-pin region 2-2-2, the exposed region 2-1 can be stably supported as compared with the embodiments described above.

FIG. 20B is a perspective plan view showing a semiconductor package 1 according to a variation of the present embodiment. In the variation shown in FIG. 20B, the power supply section 2 additionally has power supply lead parts 2-4 and 2-5. Moreover, the ground section 4 additionally has a ground lead part 4-3. The power supply lead part 2-4 is branched from the corner power supply hanging-pin region 2-2-2 and is protruded on a side of the sealing body 5 in a manner similar to the signal lead. The power supply lead part 2-5 is linked to the central power supply hanging-pin region 2-2-1 and is protruded on a side of the sealing body 5. The ground lead part 4-3 is coupled to the ground hanging-pin region 4-2 and is protruded on a side of the sealing body 5. With this construction, a power supply voltage and a reference voltage (ground reference voltage) of 0 V can be applied also from the power supply lead parts 2-4, 2-5, and the ground lead part 4-3. Thus, impedance between the power supply and the ground can be further reduced. The first to fifth embodiments are described. However, these embodiments are not independent of each other but can be also used in combination within a range in which a contradiction does not arise.

Further, the semiconductor package 1 according to the present invention can be preferably used for a vehicle-mounted microcomputer and a disk drive device.

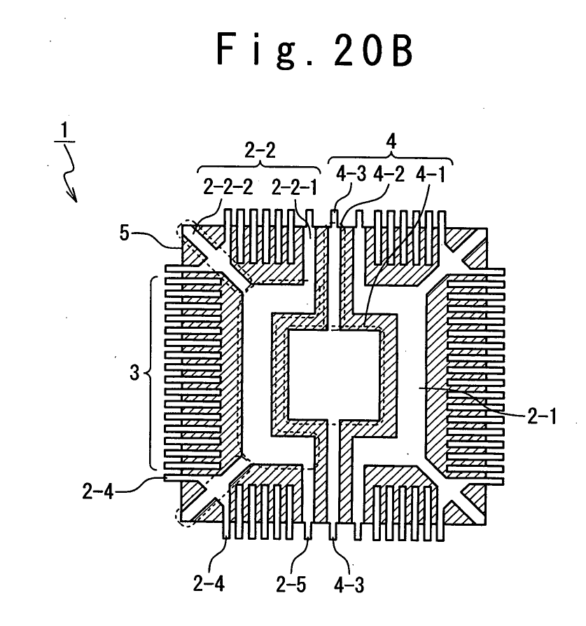

FIG. 21 is a schematic cross section view showing a case where the semiconductor package of the present invention is applied to a vehicle-mounted microcomputer. This vehicle-mounted microcomputer has a wiring board 8 and a semiconductor package 1 mounted on the wiring board 8. The wiring board 8 is connected to a device (not shown) placed in an automobile. A semiconductor chip 70, which is included in the semiconductor package 1 and is mounted with a vehicle-mounted microcomputer, has a function of controlling the device placed in the automobile. According to the present invention, a control device is provided, in which a vehicle-mounted microcomputer is provided in the semiconductor package 1, and an automobile having the semiconductor package 1 is also provided.

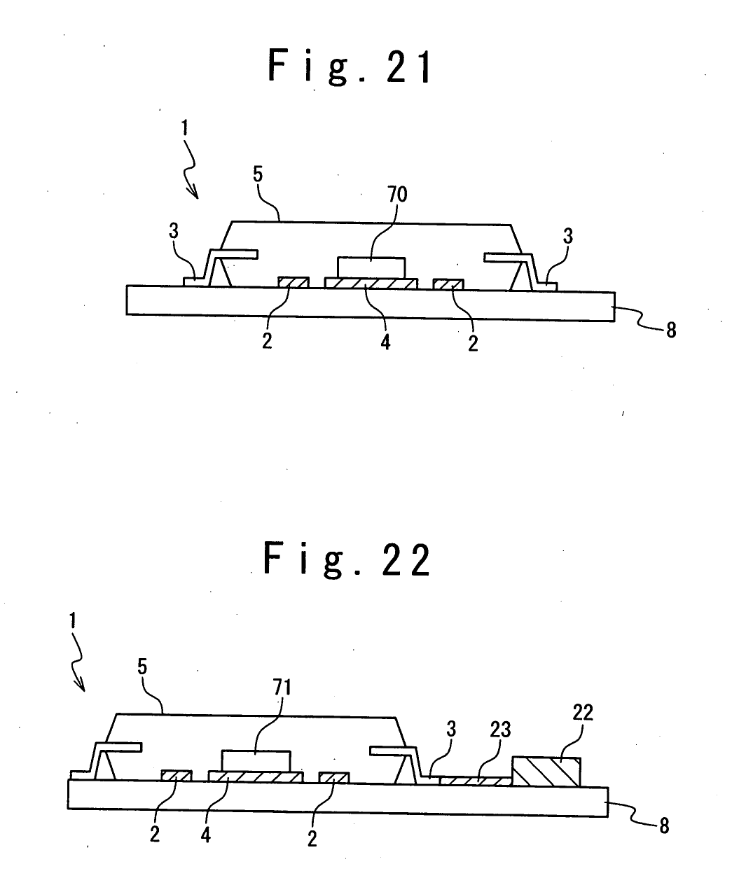

FIG. 22 is a schematic cross section view showing a control device of a disk drive device. This disk drive device has a wiring board 8, a semiconductor package 1 mounted on the wiring board 8, and an optical disk reading/writing mechanism 22 mounted on the wiring board 8. The semiconductor package 1 and the optical disk reading/writing mechanism 22 are connected to each other by a wiring 23 formed on the wiring board 8. The semiconductor chip included in the semiconductor package 1 acts as a semiconductor chip 71 for a disk drive device to control an operation of the optical disk reading/writing mechanism 22.

The cases where the leads are arranged vertically to the respective sides of the semiconductor package are shown in the drawings of the embodiments described above. However, regardless of these cases, it goes without saying that the leads may be arranged radially from the semiconductor chip.

### (Supplementary Note 1)

A vehicle-mounted microcomputer, including a semiconductor package, wherein the semiconductor package includes:

a conduction member;

a semiconductor chip mounted on and electrically connected to the conduction member; and

a sealing body configured to seal the conduction member and the semiconductor chip,

wherein the conduction member includes:

a power supply section configured to supply a power voltage to the semiconductor chip;

a ground section configured to supply a ground voltage to the semiconductor chip; and

a signal section connected to a signal terminal of the semiconductor chip,

wherein the power supply section, the ground section, and the signal section are arranged so as not to overlap each other,

at least a part of the ground section is exposed on an under surface of the sealing body, and

the power supply section includes:

an exposed region of which bottom surface is exposed on the under surface; and

a plurality of power hanging-pin region configured to extend to a side of the sealing body from the exposed region.

### (Supplementary Note 2)

A control device, including a vehicle-mounted microcomputer, wherein the vehicle-mounted microcomputer includes a semiconductor package, and

the semiconductor package includes:

a conduction member;

a semiconductor chip mounted on and electrically connected to the conduction member; and

a sealing body configured to seal the conduction member and the semiconductor chip,

wherein the conduction member includes:

a power supply section configured to supply a power voltage to the semiconductor chip;

a ground section configured to supply a ground voltage to the semiconductor chip; and

a signal section connected to a signal terminal of the semiconductor chip,

wherein the power supply section, the ground section, and the signal section are arranged so as not to overlap each other,

at least a part of the ground section is exposed on an under surface of the sealing body, and

the power supply section includes:

an exposed region of which bottom surface is exposed on the under surface; and

a plurality of power hanging-pin region configured to extend to a side of the sealing body from the exposed region.

### (Supplementary Note 3)

A vehicle including a semiconductor package, wherein the semiconductor package includes:

a conduction member;

a semiconductor chip mounted on and electrically connected to the conduction member; and

a sealing body configured to seal the conduction member and the semiconductor chip,

wherein the conduction member includes:

a power supply section configured to supply a power voltage to the semiconductor chip;

a ground section configured to supply a ground voltage to the semiconductor chip; and

a signal section connected to a signal terminal of the semiconductor chip,

wherein the power supply section, the ground section, and the signal section are arranged so as not to overlap each other,

at least a part of the ground section is exposed on an under surface of the sealing body, and

the power supply section includes:

an exposed region of which bottom surface is exposed on the under surface; and

a plurality of power hanging-pin region configured to extend to a side of the sealing body from the exposed region.

### (Supplementary Note 4)

A semiconductor device for controlling a disk drive including:

a semiconductor package; and

an optical disk reading/writing mechanism configured to read and write on an optical disk device,

wherein the semiconductor package includes:

a conduction member;

a semiconductor chip mounted on and electrically connected to the conduction member; and

a sealing body configured to seal the conduction member and the semiconductor chip,

wherein the conduction member includes:

a power supply section configured to supply a power voltage to the semiconductor chip;

a ground section configured to supply a ground voltage to the semiconductor chip; and

a signal section connected to a signal terminal of the semiconductor chip,

wherein the power supply section, the ground section, and the signal section are arranged so as not to overlap each other,

at least a part of the ground section is exposed on an under surface of the sealing body, and

the power supply section includes:

an exposed region of which bottom surface is exposed on the under surface; and

a plurality of power hanging-pin region configured to extend to a side of the sealing body from the exposed region, and

the semiconductor chip controls an operation of the optical disk reading/writing mechanism.

### (Supplementary Note 5)

A method for manufacturing a semiconductor package, including:

preparing a lead frame, wherein the lead frame includes a frame part and a conducting section,

extending to inside of the frame part from the frame part;

mounting a semiconductor chip on the conducting section;

electrically connecting the semiconductor chip and the conducting section by a bonding wire;

sealing the conducting section and the semiconductor chip; and

cutting the conducting section to be separated from the frame section, after the sealing;

wherein the preparing includes punching or etching a conductive plate to form the frame part and the conducting section, and

the conducting section includes:

a power supply section for supplying a power voltage to the semiconductor chip;

a ground section for supply a ground voltage to the semiconductor chip; and

a signal section for inputting and outputting a signal, and

the power supply section includes:

an exposed region; and

a plurality of power supply hanging-pin regions configured to extend to the frame section from the exposed region, and

the sealing includes exposing the exposed region and a part of the ground section on an under surface of a sealing body.

What is claimed is:

1. A semiconductor package, comprising:
a conduction member;
a semiconductor chip mounted on and electrically connected to said conduction member; and
a sealing body configured to seal said conduction member and said semiconductor chip,
wherein said conduction member comprises:
a power supply section configured to supply a power voltage to said semiconductor chip;
a ground section configured to supply a ground voltage to said semiconductor chip; and
a signal section connected to a signal terminal of said semiconductor chip,
wherein said power supply section, said ground section, and said signal section are arranged so as not to overlap each other, and
at least a part of said ground section is exposed on an under surface of said sealing body,
said power supply section comprises:
an exposed region of which bottom surface is exposed on said under surface; and
a plurality of power hanging-pin region configured to extend to a side of said sealing body from said exposed region.

2. The semiconductor package according to claim 1, wherein said ground section comprises an island part, and
said island part comprises;
a principal surface of said island part on which said semiconductor chip is mounted, and
a bottom surface of said island part exposed on said under surface,
wherein said power supply section is arranged on outside of said island region.

3. The semiconductor package according to claim 1, wherein said sealing body has a rectangular solid shape, and
each of said plurality of power hanging-pin region extends to a corner of said sealing body from said exposed region.

4. The semiconductor package according to claim 1, wherein each of said plurality of power hanging-pin regions comprises;
a corner power hanging-pin region configured to extend to a corner of said sealing body from said exposed region, and
a central power hanging-pin region configured to extend to a central portion of a side of said sealing body.

5. The semiconductor package according to claim 2, wherein said ground section further comprises, a plurality of ground hanging-pin regions each extending to a side of said sealing body from said island part.

6. The semiconductor package according to claim 5, wherein each of said plurality of ground hanging-pin regions extends to a central portion of said side of the sealing body.

7. The semiconductor package according to claim 5, wherein each of said plurality of ground hanging-pin regions extends to a corner of said sealing body.

8. The semiconductor package according to claim 2, wherein said semiconductor chip is mounted on both of said exposed region and said island part.

9. The semiconductor package according to claim 8, wherein a distance between said exposed region and said island part on a principal surface is narrower than that on a bottom surface.

10. The semiconductor package according to claim 1, wherein said signal section comprises a plurality of signal lead, and
each of said plurality of signal leads protrudes to outside through a side surface of said sealing body.

11. The semiconductor package according to claim 1, wherein said power supply section comprises a power lead part protruding to outside through a side surface of said sealing body, and
said ground section comprises a ground lead part protruding to outside through said side surface.

12. The semiconductor package according to claim 1, wherein said conduction member has a flat shape, and said conduction member is arranged on a plane including said under surface.

13. The semiconductor package according to claim 1, further comprising a decoupling capacitor configured to be sealed with said sealing body,
wherein said decoupling capacitor is electrically connected to said power supply section at one end and is electrically connected to said ground section at another end.

14. The semiconductor package according to claim 1, wherein said signal section, said ground section and said exposed region of said power supply section have flat shape and are arranged on a plane including said under surface.

15. A lead frame, comprising:
a frame part configured to have a frame shape; and
a conduction member configured to extend to inside of said frame part,
wherein said conduction member comprises:
a power supply section for supplying a power voltage to a semiconductor chip mounted on said conduction member;
a ground section for supplying a ground voltage to said semiconductor chip; and
a signal section for inputting and outputting a signal,
said power supply section comprises:
an exposed region; and
a plurality of power hanging-pin regions configured to couple said frame part and said exposed region to support said exposed region,
wherein said conduction member is provided so as not to overlap.

16. A wiring board on which a semiconductor package is mounted, comprising:
a power supply terminal provided on a principal surface of said wiring board;
a ground terminal provided on said principal surface; and
decoupling capacitor provided on a bottom surface of said wiring board,
wherein said semiconductor package comprises:
a conduction member;
a semiconductor chip mounted on and electrically connected to said conduction member; and
a sealing body configured to seal said conduction member and said semiconductor chip,
wherein said conduction member comprises:
a power supply section configured to supply a power voltage to said semiconductor chip;
a ground section configured to, supply a ground voltage to said semiconductor chip; and
a signal section connected to a signal terminal of said semiconductor chip,
wherein said power supply section, said ground section, and said signal section are arranged so as not to overlap each other,
at least a part of said ground section is exposed on an under surface of said sealing body, and
said power supply section comprises:
an exposed region of which bottom surface is exposed on said under surface; and
a plurality of power hanging-pin regions configured to extend to a side of said sealing body from said exposed region,
said power supply terminal is connected to said power supply section on said under surface,
said ground terminal is connected to said ground section on said under surface,
one end of said decoupling capacitor is electrically connected to said power supply terminal via a through hole, and
another end of said decoupling capacitor is electrically connected to said ground terminal via a through hole.
